(19) United States
(12) Patent Application Publication
(10) Pub. No.: US 2016/0198568 A1
(43) Pub. Date: Jul. 7, 2016

(54) PRINTED CIRCUIT BOARD AND ELECTRONIC COMPONENT MODULE

(71) Applicant: Samsung Electro-Mechanics Co., Ltd., Suwon-si (KR)

(72) Inventors: Mi Jin PARK, Suwon-si (KR); Kyoung Moo HARR, Suwon-si (KR); Seung Wan SHIN, Suwon-si (KR)

(73) Assignee: Samsung Electro-Mechanics Co., Ltd., Suwon-si (KR)

(21) Appl. No.: 14/987,291

(22) Filed: Jan. 4, 2016

(30) Foreign Application Priority Data
Jan. 7, 2015 (KR) 10-2015-0002109

(51) Int. Cl. H05K 1/02; H05K 1/18; H05K 1/11

(52) U.S. Cl. CPC H05K 1/0284; H05K 1/0298; H05K 1/111; H05K 1/112; H05K 1/181

(57) ABSTRACT

A printed circuit board includes a first insulating layer including a first circuit pattern, a second insulating layer including a second circuit pattern, and a dummy pattern disposed in the first insulating layer and the second insulating layer, in which the first and second insulating layers are made of different materials. An electronic component module includes a printed circuit board and an electronic component mounted on the printed circuit board.

### CROSS-REFERENCE TO RELATED APPLICATION

This application claims the benefit under 35 USC 119(a) of Korean Patent Application No. 10-2015-0002109, filed on Jan. 7, 2015, in the Korean Intellectual Property Office, the entire disclosure of which is incorporated herein by reference for all purposes.

### BACKGROUND

1. Field

The present disclosure relates to a printed circuit board and an electronic component module.

2. Description of Related Art

Recently, functional capacities provided by smartphones and tablet personal computers, as well as battery consumption and expected battery life have drastically increased. However, battery technology still presents limitations regarding the amount of energy that may be stored. Thus, battery volume has increased in order to increase capacity. In turn, the demand for producing thinner and smaller components for electronic devices has increased.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a printed circuit board includes a first insulating layer including a first circuit pattern, a second insulating layer including a second circuit pattern, and a dummy pattern disposed in the first insulating layer and the second insulating layer, and the first and second insulating layers are made of different materials.

The second insulating layer may be embedded in the first insulating layer such that an upper surface of the second insulating layer is exposed from the first insulating layer.

The dummy pattern may be disposed at an interface between the first insulating layer and the second insulating layer, the dummy pattern being electrically isolated from the first circuit pattern and the second circuit pattern.

The second insulating layer may be embedded in the first insulating layer such that an upper surface of the second insulating layer is exposed from the first insulating layer, and the dummy pattern may be embedded in the first and second insulating layers such that an upper surface of the dummy pattern is exposed from the first and second insulating layers.

Upper surfaces of the first insulating layer, the second insulating layer, and the dummy pattern may be coplanar.

The second insulating layer may be a photosensitive insulating layer.

The second circuit pattern may include a pattern including a pitch finer than a pitch of the first circuit pattern.

The second circuit pattern may include a plurality of pads and a connection pattern for mounting of components, and the plurality of pads may be electrically connected to each other by the connection pattern.

The second circuit pattern may further include connection vias connecting the plurality of pads and the connection pattern to each other.

The plurality of pads may be embedded in the second insulating layer such that upper ends of the plurality of pads are exposed.

The first circuit pattern may include a plurality of pads embedded in the first insulating layer such that upper ends of the plurality of pads are exposed.

In another general aspect, an electronic component module includes a printed circuit board including a first insulating layer including a first circuit pattern, a second insulating layer embedded in the first insulating layer such that an upper end of the second insulating layer is exposed, the second insulating layer including a micro-circuit structure including a connection pattern for a connection of a pair of components, and a dummy pattern disposed in the first insulating layer and the second insulating layer, the first and second insulating layers being made of different materials; and an electronic component mounted on the printed circuit board, and the electronic component includes a pair of components connected to each other by the connection pattern.

The micro-circuit structure may include a pattern having a pitch finer than a pitch of the first circuit pattern.

The dummy pattern may be embedded in the first and second insulating layers such that an upper surface of the dummy pattern is exposed from the first insulating layer and the second insulating layer.

The micro-circuit structure may further include a pair of pads and a pair of connection vias respectively connecting both ends of the connection pattern and a pair of components to each other.

Other features and aspects will be apparent from the following detailed description, the drawings, and the claims.

### BRIEF DESCRIPTION OF THE DRAWINGS

FIG. 1 is a cross-sectional view illustrating an example of a printed circuit board.

FIG. 2 is a cross-sectional view illustrating an example of an electronic component module.

FIG. 3 is a flow chart illustrating an example of a method of manufacturing a printed circuit board.

FIGS. 4 through 15 are cross-sectional views sequentially illustrating an example of the method of manufacturing a printed circuit board.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

In the drawings, the shapes and dimensions of elements may be exaggerated for clarity, and the same reference numerals will be used throughout to designate the same or like elements.

Printed Circuit Board

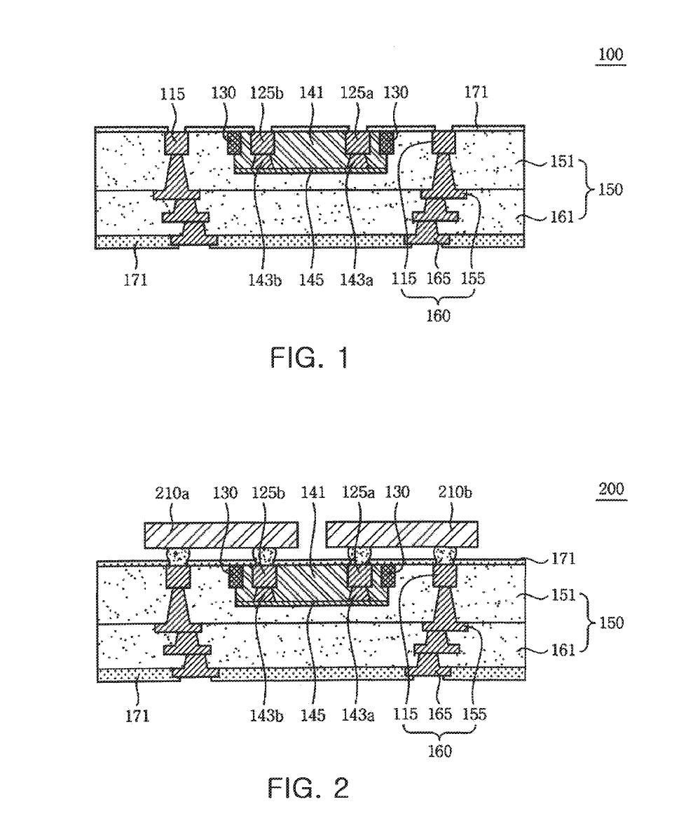

FIG. 1 illustrates a cross-sectional view of an example of a printed circuit board.

Referring to FIG. 1, the printed circuit board 100 includes a first insulating layer 150 having a first circuit pattern 160, a second insulating layer 141 having a second circuit pattern, and a dummy pattern 130 formed in both the first insulating layer 150 and the second insulating layer 141 by being disposed at the interface between the first insulating layer 150 and the second insulating layer 141.

The first and second insulating layers 150 and 141 may be formed of heterogeneous materials.

In this example, the first insulating layer 150 includes a plurality of insulating layers 151 and 161. The first insulating layer 150 may be formed of any insulating resin generally used as an insulating material in printed circuit boards.

According to the present embodiment, a material of the first insulating layer 150 may be a resin used for a general coreless board, such as a thermosetting resin such as an epoxy resin or a thermoplastic resin such as polyimide, but is not limited thereto. For example, the first insulating layer 150 may be formed of a resin such as Ajinomoto build-up film (ABF), FR-4, bismaleimide triazine (BT), or the like.

The first circuit pattern 160 may be formed inside and outside the first insulating layer 150.

As illustrated in FIG. 1, the first circuit pattern 160 may include a plurality of pads 115 embedded in the first insulating layer 150 so that upper ends of the plurality of pads 115 are exposed.

The first circuit pattern 160 may also include a plurality of circuit layers 155 and 165.

Interlayer circuit layers of the first circuit pattern 160 may be electrically connected to each other by a general connection via.

The second insulating layer 141 may be formed of a material different from that of the first insulating layer 150.

The second insulating layer 141 may be a photosensitive dielectric layer in order to facilitate formation of a micro-circuit structure. For example, a photosensitive dielectric layer that does not contain a glass sheet may be used as the second insulating layer 141.

In this example, the second insulating layer 141 is embedded in the first insulating layer 150 so that an upper surface thereof is exposed from the first insulating layer 150.

The second circuit pattern, which is the micro-circuit structure, may be formed inside and outside the second insulating layer 141.

The second circuit pattern may include a pattern having a pitch finer than that of the first circuit pattern 160.

In this example, the second circuit pattern includes a connection pattern 145 that may serve as a signal line that connects a plurality of electronic components to each other.

The second circuit pattern also includes a plurality of pads 125a and 125b for mounting the plurality of electronic components. The plurality of pads 125a and 125b are connected to the connection pattern 145 through a plurality of connection vias 143a and 143b.

The connection vias 143a and 143b, which are fine vias, may have a diameter of, for example, 5 μm to 35 μm.

The plurality of pads 125a and 125b are embedded in the second insulating layer 141 so that upper ends thereof are exposed from the second insulating layer 141.

According to the present embodiment, the micro-circuit structure including a micro-circuit and vias having a small diameter as well as the embedded pattern may be implemented in the outermost layer, thereby enabling connection between the electronic components in the printed circuit board.

Referring the example illustrated in FIG. 1, the dummy pattern 130 is embedded in the first and second insulating layers 150 and 141 so that an upper surface thereof is exposed from the first insulating layer 150 and the second insulating layer 141.

In this example, upper surfaces of the first insulating layer 150, the second insulating layer 141, and the dummy pattern 130 are coplanar.

The dummy pattern 130 may be formed together with the circuit pattern when the circuit pattern is formed, and may be formed of the same material as that of a general circuit pattern. For example, the dummy pattern 130 may be formed of a metal or a conductive material such as copper (Cu).

In a case of an existing coreless board in which a board technology and a semiconductor technology are combined, adhesion between two different insulating materials is weaker in comparison to the adhesion obtained between insulating materials made of the same material are joined together. In addition, when the two insulating materials are used, a void or the like may occur in the bonded position between the two different insulating materials, or an abrupt step may form on the surface along the interface of the two different insulating materials. This kind of irregularity may contribute to the formation of a weak point that is detected during a reliability test such as a highly accelerated stress test (HAST), high temperature storage (HTS), or the like. Further, the interface area may cause other reliability or yield problem due to moisture absorption and the like.

According to the illustrated example, the dummy pattern is inserted into the bonded portion that is externally exposed at the interface between the two different insulating materials. Thereby, the dummy pattern may prevent the weak bonded portion from being exposed to an outside of the printed circuit board, and eliminate the abrupt step that may form at the bonded portion between the two different insulating materials. In addition, optionally, the surface of the dummy pattern may be provided with roughness to increase adhesion between the dummy pattern and the insulating layers.

Additionally, a general liquid-phase or film-type solder resist layer 171 may be formed as a protective layer exposing the plurality of pads 115, 125a, and 125b, on the outermost insulating circuit layer.

The solder resist layer may be formed in order to protect circuit patterns of the outermost layer and electrically insulate the circuit patterns from each other, and have opening parts formed therein in order to expose pads of the outermost layer connected to an external product.

In addition, a surface treatment layer may be selectively and additionally formed on the pads exposed through the opening parts of the solder resist layer.

The surface treatment layer may be formed by any method known in the art, such as electro gold plating, immersion gold plating, organic solderability preservative (OSP) or immersion tin plating, immersion silver plating, direct immersion gold (DIG) plating, hot air solder leveling (HASL), or the like.

The pads formed as described above may be used as pads for wire bonding or pads for bumps, or may be used as pads for solder balling for mounting external connection terminals such as solder balls, depending on a purpose thereof.

Electronic Component Module

FIG. 2 illustrates an example of an electronic component module. A description of components overlapping those of the printed circuit board described above among components of the electronic component module illustrated in FIG. 2 will be omitted.

Referring to FIG. 2, the electronic component module 200 includes electronic components mounted on the printed circuit board.

Electronic components 210a and 210b may include various electronic devices such as a passive device and an active device, and may include any electronic devices that may be generally mounted on or embedded in the printed circuit board.

In this example, the printed circuit board 100 includes a first insulating layer 150 having a first circuit pattern 160, a second insulating layer 141 having a micro-circuit structure including a connection pattern 145 for connecting a pair of electronic components 210a and 210b to each other, and a dummy pattern 130 formed in the first insulating layer 150 and the second insulating layer 141.

The second insulating layer 141 is embedded in the first insulating layer 150 so that an upper surface thereof is exposed from the first insulating layer 150. The upper surfaces of the first insulating layer 150 and the second insulating layer 141 are coplanar.

The first and second insulating layers 150 and 141 may be formed of two different materials.

In this example, the micro-circuit structure includes the connection pattern 145 serving as a signal line connecting the pair of electronic components 210a and 210b to each other. In addition, the micro-circuit structure includes a pair of pads 125a and 125b for mounting the pair of electronic components. The pair of pads 125a and 125b are connected to the connection pattern 145 through a pair of connection vias 143a and 143b. However, the arrangement of the second circuit pattern is not limited to the illustrated example.

The connection vias 143a and 143b, which are fine vias, may have a diameter of, for example, 5 μm to 35 μm.

The pair of pads 125a and 125b may be embedded in the second insulating layer 141 so that upper ends thereof are exposed.

According to the present embodiment, the micro-circuit structure including a micro-circuit and vias having a small diameter as well as the embedded pattern may be implemented in the outermost layer, thereby enabling connection between the electronic components in the printed circuit board.

Referring to FIG. 2, the dummy pattern 130 is embedded in the first and second insulating layers 150 and 141 so that an upper surface thereof is exposed from the first insulating layer 150 and the second insulating layer 141. Therefore, the dummy pattern is inserted into an externally exposed area of the bonded portion or interface between two different insulating materials. Accordingly, it is possible to prevent the weak portion of the printed circuit board 100 from being exposed to outside, and to alleviate the formation of an abrupt step at the interface of the two different insulating materials. In addition, optionally, the surface of the dummy pattern may be made rough so as to increase adhesion between the dummy pattern and the insulating layers.

Method of Manufacturing Printed Circuit Board

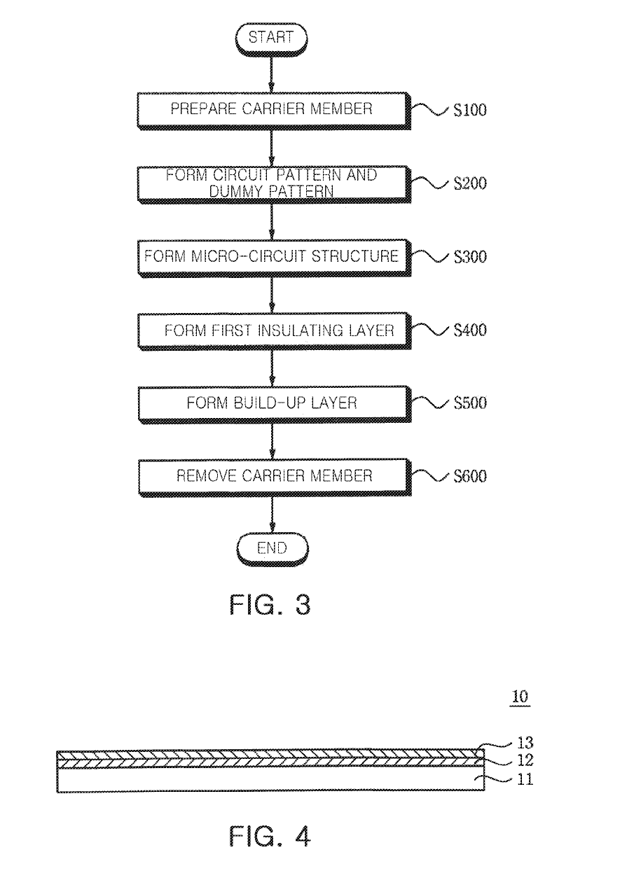

FIG. 3 illustrates a flow chart of an example of a method of manufacturing a printed circuit board. FIGS. 4 through 15 are cross-sectional views sequentially illustrating the example of the method of manufacturing the printed circuit board.

Referring to FIG. 3, the method of manufacturing a printed circuit board includes preparing a carrier member (S100), forming a circuit pattern and a dummy pattern (S200), forming a micro-circuit structure (S300) after forming an insulating material, forming a first insulating layer (S400), forming a build-up layer (S500), and removing the carrier member (S600).

Hereinafter, respective processes will be described with reference to cross-sectional views illustrated in FIGS. 4 through 15.

First, referring to FIG. 4, the carrier member 10 is prepared.

The carrier member 10 includes a carrier core 11 and first and second metal layers 12 and 13 sequentially formed on one surface of the carrier core 11. However, in another example, the first and second metal layers 12 and 13 may be sequentially formed on both surfaces of the carrier core 11.

The carrier core 11, which supports an insulating layer, a circuit layer, and the like, when the insulating layer, the circuit layer, and the like, are formed, may be formed of an insulating material or a metal.

The first metal layer 12 may be formed of copper. However, a material of the first metal layer 12 is not limited thereto.

The second metal layer 13 may serve as a seed layer and be formed of copper.

However, the above-mentioned carrier member 10 may be only an example, and is not limited in the embodiment as long as it is used as a support board in a circuit board field and may be later detached or removed.

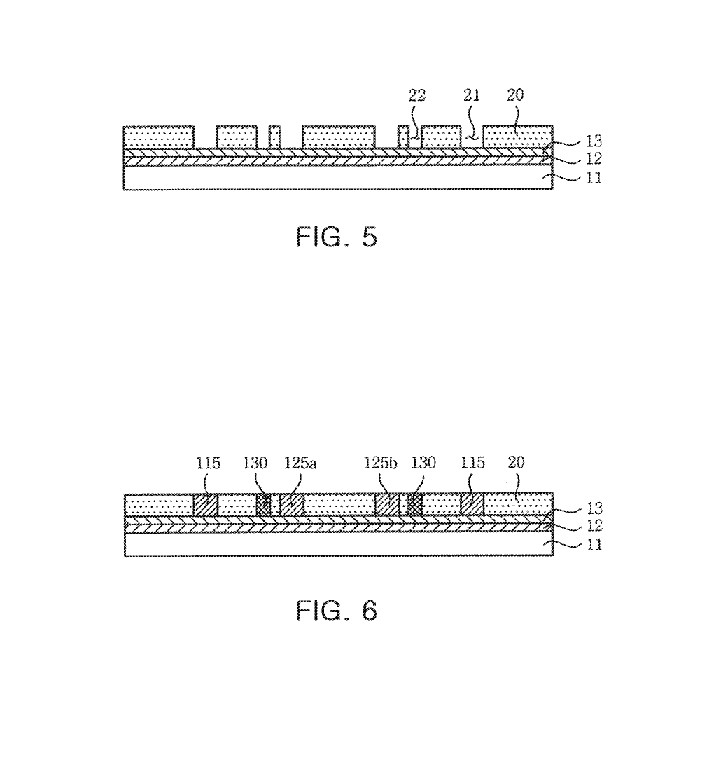

Next, referring to FIG. 5, a resist pattern 20 having predetermined opening parts is formed on the carrier member.

In detail, after a liquid-phase plating resist is applied onto the carrier member, general exposure and development may be performed on the carrier member onto which the liquid-phase plating resist is applied, thereby forming the predetermined opening parts including opening parts 21 for forming a circuit pattern and opening parts 22 for forming a dummy pattern.

In a case in which the plating resist is applied in a liquid-phase form, uniformity of a thickness may be high, and thus it may be easy to later form a micro-circuit structure.

Next, referring to FIG. 6, a plating layer is provided in the opening parts 21 and 22 through plating to form the circuit pattern including the plurality of pads 115, 125a, and 125b and the dummy pattern 130.

The plating may be electroless plating, electroplating, or a combination thereof, and may be copper plating.

Additionally, roughness may be formed on the dummy pattern 130 to make a surface of the dummy pattern rough, thereby later improving bonding characteristics between the dummy pattern 130 and the insulating layer.

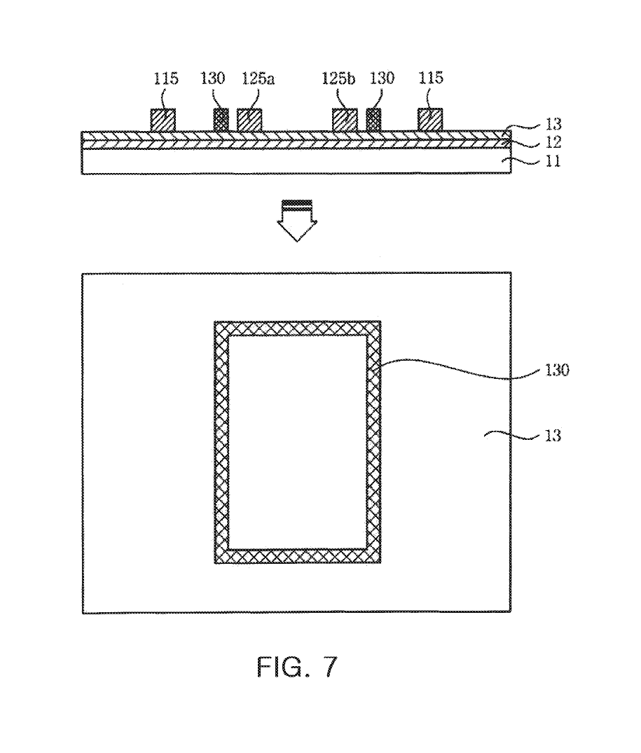

Next, referring to FIG. 7, the resist pattern 20 is removed.

Referring to a plan view illustrated at a lower portion of FIG. 7, the dummy pattern 130 formed by removing the resist pattern 20 may have, for example, a quadrangular frame shape when viewed from above.

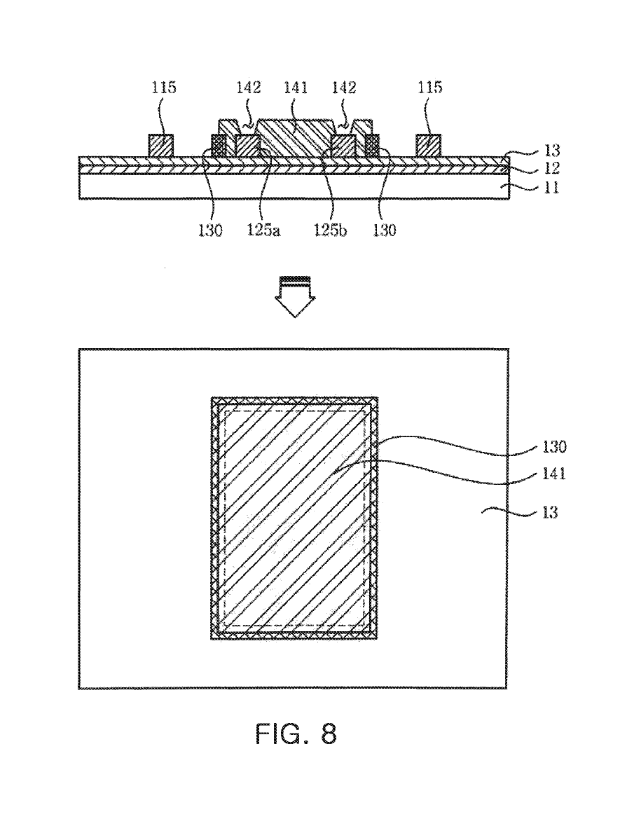

Next, referring to FIG. 8, the second insulating layer 141 covering a portion of the dummy pattern 130 while covering the pair of pads 125a and 125b in a region of the micro-circuit structure is formed, and micro via-holes 142 for connection vias is formed.

As the second insulating layer 141, a photosensitive insulating layer having surface roughness lower than that of a general resin insulating layer may be used in order to facilitate formation of the micro-circuit structure.

The micro via-holes 142 is formed with a diameter of, for example, about 5 μm to 35 μm through laser beam machining.

Referring to a plan view illustrated at a lower portion of FIG. 8, as a result, the second insulating layer 141 is formed at an inner side of the dummy pattern 130 to cover a portion of the inner side of the dummy pattern 130 having the quadrangular frame shape.

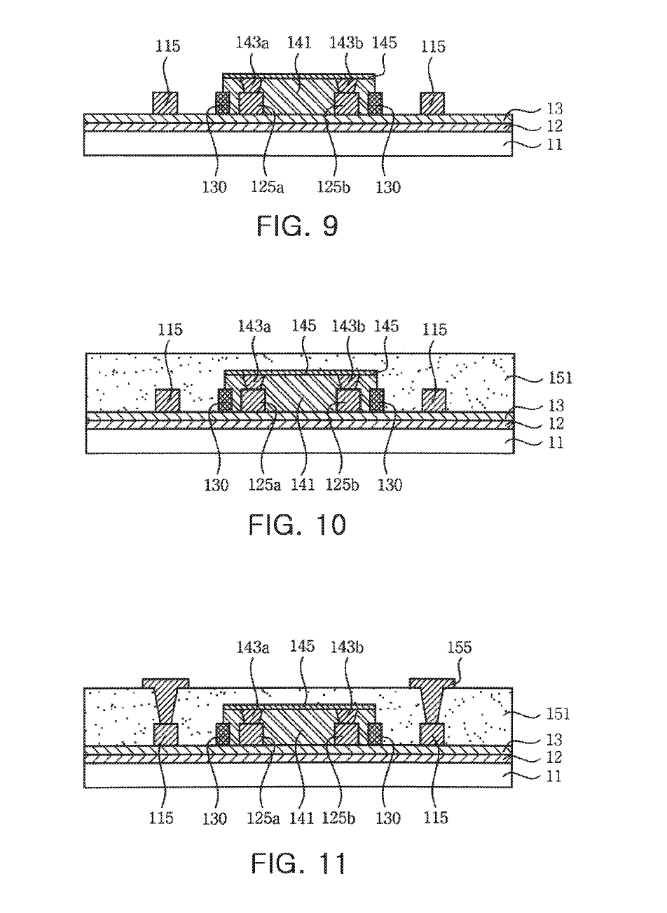

Next, referring to FIG. 9, plating is performed on the second insulating layer 141 to form the micro-circuit structure including the pair of connection vias 143a and 143b and the connection pattern 145, which is a micro-circuit.

The plating may be electroless plating, electroplating, or a combination thereof, and may be copper plating.

Through the process as described above, the pair of pads 125a and 125b for mounting the electronic components and the connection pattern 145 may be electrically connected to each other through the connection vias 143a and 143b.

The connection pattern 145 may serve as a signal line connecting the plurality of electronic components to each other.

Additionally, plasma processing may later be performed on the micro-circuit structure, in order to increase close adhesion between the micro-circuit structure and the insulating layer.

Next, referring to FIG. 10, an insulating layer 151 is formed on the carrier member to cover the micro-circuit structure and a circuit pattern including the pads 115.

The insulating layer 151 and the second insulating layer 141 may be formed of two different materials.

The insulating layer 151 may be formed of any insulating resin generally used as an insulating material in a printed circuit board.

According to the present embodiment, a material of the insulating layer 151 may be a resin used for a general coreless board, such as a thermosetting resin such as an epoxy resin or a thermoplastic resin such as polyimide, but is not limited thereto. For example, the insulating layer 151 may be formed of a resin such as ABF, FR-4, BT, or the like.

Next, referring to FIG. 11, a circuit layer 155 including vias is formed on the insulating layer 151.

The circuit layer 155 may be formed by laser beam machining and a semi-additive process (SAP) depending on a general method of forming a circuit pattern.

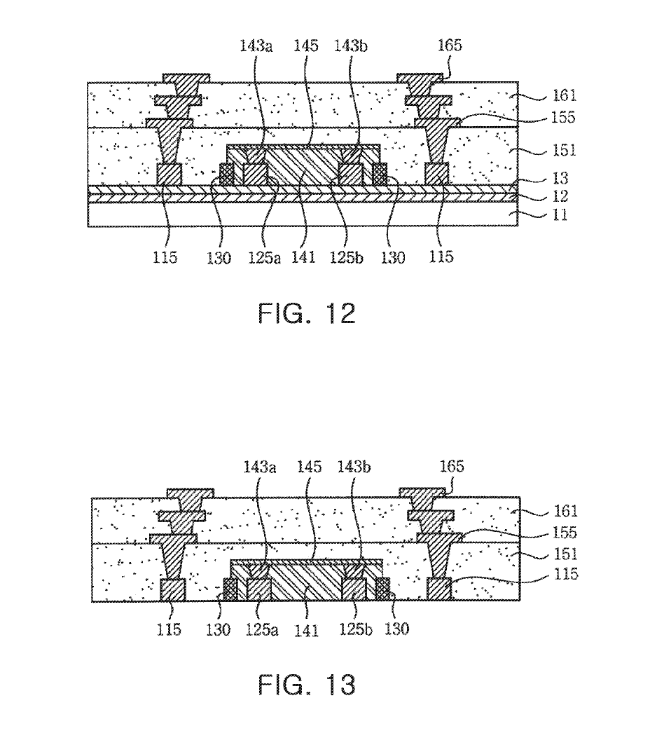

Next, referring to FIG. 12, a process of stacking a build-up insulating layer 161 and a general process of forming a build-up circuit layer 165 are repeated to form a desired number of build-up layers. The stacking of the build-up insulating layer 161 and the general process of forming the build-up circuit layer 165 may be performed by laser beam machining and a semi-additive process (SAP), for example.

The build-up insulating layer 161 and the second insulating layer 141 may be formed of two different materials.

The build-up insulating layer 161 may be formed of any insulating resin generally used as an insulating material in a printed circuit board.

According to the present embodiment, a material of the build-up insulating layer 161 may be a resin used for a general coreless board, such as a thermosetting resin such as an epoxy resin or a thermoplastic resin such as polyimide, but is not limited thereto. For example, the insulating layer 151 may be formed of a resin such as ABF, FR-4, BT, or the like.

Next, referring to FIG. 13, the carrier member is removed.

The carrier member may be removed by detaching the carrier core 11 and the first metal layer 12 and then removing the second metal layer 13.

A method of removing the carrier member is not limited. For instance, the carrier member may be removed by various methods depending on a configuration of an actually used carrier member.

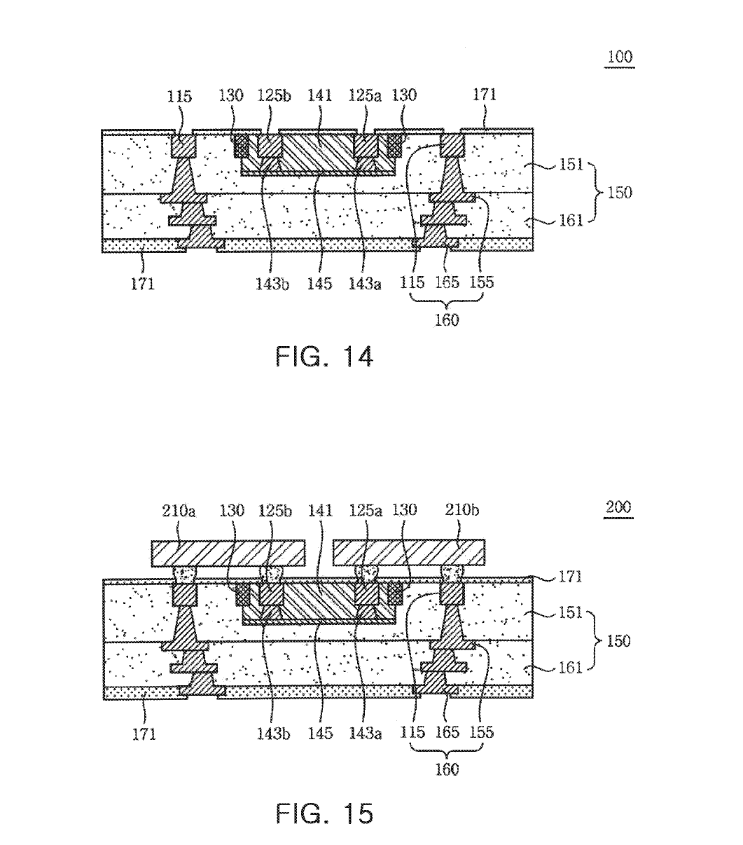

Next, referring to FIG. 14, a general liquid-phase or film-type solder resist layer 171 is formed as a protective layer exposing the plurality of pads 115, 125a, and 125b on the outermost insulating circuit layer.

The solder resist layer may be formed in order to protect circuit patterns of the outermost layer and electrically insulate the circuit patterns from each other, and have opening parts formed therein in order to expose pads of the outermost layer connected to an external product.

In addition, a surface treatment layer may be selectively and additionally formed on the pads exposed through the opening parts of the solder resist layer.

The surface treatment layer may be formed by any method known in the art, such as electro gold plating, immersion gold plating, organic solderability preservative (OSP) or immersion tin plating, immersion silver plating, direct immersion gold (DIG) plating, hot air solder leveling (HASL), or the like.

Next, referring to FIG. 15, the electronic components 210a and 210b are mounted on the plurality of pads 115, 125a, and 125b with general solder balls interposed therebetween.

The electronic components 210a and 210b may include various electronic devices such as a passive device and an active device, and may include any electronic devices that may be generally mounted on or embedded in the printed circuit board.

As illustrated in FIG. 15, the pair of electronic components 210a and 210b are connected to each other by the connection pattern 145 formed in the micro-circuit structure of the printed circuit board.

According to the present embodiment, a circuit pattern including pads of a surface on which the electronic components are mounted may be implemented as an embedded pattern, and the micro-circuit structure may be introduced into the outermost insulating layer, thereby enabling connection between the electronic components in the printed circuit board through the fine pattern.

Further, the dummy pattern may be inserted into the externally exposed bonded portion between two different insulating materials in order to form the micro-circuit structure, thereby preventing as much as possible the weak portion of the printed circuit board from being exposed and alleviating the formation of an abrupt step along the interface between the two insulating materials.

Therefore, electrical characteristics including impedance may be improved.

Provided above is an example of a printed circuit board in which bonding characteristics between heterogeneous insulating materials may be improved, and a method of manufacturing the same.

In the example of the printed circuit board, an abrupt step that may form at an interface between two different insulating materials may be alleviated, thereby improving the reliability of a connection structure between electronic components.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board comprising:
a first insulating layer comprising a first circuit pattern;
a second insulating layer comprising a second circuit pattern; and
a dummy pattern disposed in the first insulating layer and the second insulating layer,
wherein the first and second insulating layers are made of different materials.

2. The printed circuit board of claim 1, wherein the second insulating layer is embedded in the first insulating layer such that an upper surface of the second insulating layer is exposed from the first insulating layer.

3. The printed circuit board of claim 1, wherein the dummy pattern is disposed at an interface between the first insulating layer and the second insulating layer, the dummy pattern being electrically isolated from the first circuit pattern and the second circuit pattern.

4. The printed circuit board of claim 1, wherein the second insulating layer is embedded in the first insulating layer such that an upper surface of the second insulating layer is exposed from the first insulating layer, and the dummy pattern is embedded in the first and second insulating layers such that an upper surface of the dummy pattern is exposed from the first and second insulating layers.

5. The printed circuit board of claim 1, wherein upper surfaces of the first insulating layer, the second insulating layer, and the dummy pattern are coplanar.

6. The printed circuit board of claim 1, wherein the second insulating layer is a photosensitive insulating layer.

7. The printed circuit board of claim 1, wherein the second circuit pattern comprises a pattern comprising a pitch finer than a pitch of the first circuit pattern.

8. The printed circuit board of claim 1, wherein the second circuit pattern comprises a plurality of pads and a connection pattern for mounting of components, and the plurality of pads are electrically connected to each other by the connection pattern.

9. The printed circuit board of claim 8, wherein the second circuit pattern further comprises connection vias connecting the plurality of pads and the connection pattern to each other.

10. The printed circuit board of claim 8, wherein the plurality of pads are embedded in the second insulating layer such that upper ends of the plurality of pads are exposed.

11. The printed circuit board of claim 1, wherein the first circuit pattern comprises a plurality of pads embedded in the first insulating layer such that upper ends of the plurality of pads are exposed.

12. An electronic component module comprising:
a printed circuit board comprising a first insulating layer including a first circuit pattern, a second insulating layer embedded in the first insulating layer such that an upper end of the second insulating layer is exposed, the second insulating layer comprising a micro-circuit structure comprising a connection pattern for a connection of a pair of components, and a dummy pattern disposed in the first insulating layer and the second insulating layer, the first and second insulating layers being made of different materials; and
an electronic component mounted on the printed circuit board,
wherein the electronic component comprises a pair of components connected to each other by the connection pattern.

13. The electronic component module of claim 12, wherein the micro-circuit structure comprises a pattern having a pitch finer than a pitch of the first circuit pattern.

14. The electronic component module of claim 12, wherein the dummy pattern is embedded in the first and second insulating layers such that an upper surface of the dummy pattern is exposed from the first insulating layer and the second insulating layer.

15. The electronic component module of claim 12, wherein the micro-circuit structure further comprises a pair of pads and a pair of connection vias respectively connecting both ends of the connection pattern and a pair of components to each other.
